(19) United States
(12) Patent Application Publication
(10) Pub. No.: US 2005/0185689 A1
(43) Pub. Date: Aug. 25, 2005

(54) Optoelectronic device having a Discrete Bragg Reflector and an electro-absorption modulator

(76) Inventors: David James Clark, Ipswich (GB); Paul Marshall Charles, Ipswich (GB)

Correspondence Address: PERMAN & GREEN, 425 POST ROAD, FAIRFIELD, CT, 06824, US

(21) Appl. No.: 10/961,639

(22) Filed: Oct. 8, 2004

(30) Foreign Application Priority Data
Oct. 10, 2003 (GB) 0323757.5

(51) Int. Cl. H01S 5/00

(52) U.S. Cl. 372/50.1; 372/50.11; 372/96

(57) ABSTRACT

A semiconductor component includes a waveguide section for guiding optical radiation, a Distributed Bragg Reflector (DBR) section for wavelength-selecting optical radiation received from the waveguide section and an Electro-absorption Modulator (EAM) section for modulating optical radiation received from the DBR section, in which each section has a waveguide layer for conveying the optical radiation, the sections being monolithically integrated on a common semiconductor substrate, the DBR section lying between the waveguide section and the EAM section with the waveguides of adjacent sections being butt-coupled and aligned so that optical radiation may be conveyed between adjacent sections.

The present invention relates to a monolithically integrated optoelectronic component, for example a laser diode source of optical radiation, having a Distributed Bragg Reflector (DBR) device and an Electro-absorption Modulator (EAM) device, and to a method of forming such a device.

Because laser diode wavelength varies by up to about 8 nm owing to laser ageing, temperature and power changes, the channel separation in a an optical communications system using wavelength division multiplexing (WDM) with no control of laser wavelength is limited to a minimum of about 20 nm. Therefore, in order to increase data transmission capacity, WDM systems commonly require sources of optical radiation each of which has a wavelength that is accurately stabilized. Each stabilized wavelength also needs to be individually modulated so that the WDM system can carry a number of discrete optical channels along an optical transmission link such as an optical fibre. It is known to manufacture such devices as a monolithically integrated optoelectronic device using a III-V semiconductor material based on an InP wafer.

A WDM system in a local area network or a “metro” network typically operates at around 1310 nm. WDM systems in a long haul optical fibre link normally operate at around 1550 nm. The wavelength is stabilized in each component by controlling the operating temperature of the optoelectronic component and by incorporating a distributed feedback (DFB) grating into each laser diode. The grating extends over the length of the laser cavity and has a fixed wavelength. This allows the channel spacing in DWDM to be as close as 0.8 nm and 0.4 nm.

Such careful control is only practical and economical at a Central Office or other main facility where the laser devices can be carefully controlled, monitored, and replaced as necessary.

WDM systems may employ up to about 60 optical channels, each at a different operating wavelength. If an optical transmitter component fails in service, then this will need to be replaced. An enterprise using the WDM may therefore need to stock at least 60 spare such components in order to ensure that any one component fails in use. As such components are relatively expensive this is quite inconvenient.

It has therefore been proposed that such optoelectronic transmitter devices have the facility to be tuned to a desired wavelength. When a device fails, then a spare component can be tuned to the wavelength of the failed device. The wavelength stabilization device used in such tuneable components is a Distributed Bragg Reflector (DBR) device. The DBR device needs to have an active layer that is substantially transparent at the optical wavelength of the laser diode The DBR device is therefore conventionally formed by first growing on a substrate the doped III-V material layers forming laser diode, then etching away a section of these grown layers, and then re-growing III-V material layers on the common substrate to form a DBR section having a waveguide layer that is butt-coupled and in-line with the laser cavity formed by the laser diode active layers.

The term “butt-coupled” is used herein to describe a semiconductor material optoelectronic component in which adjacent optoelectronic sections of the component have, on one side of a junction between adjacent sections, one or more semiconductor layers that have been grown (for example using MOVCD techniques) up against other previously formed semiconductor material on the other side of the junction.

The tuneable DBR device is then aligned with an external electro-absorption modulator (EAM) device, or alternatively an EAM device may be formed on the common substrate by re-growing doped III-V material layers with properties suitable to form the EAM device. Such EAM layers need to have different properties from those forming either the laser section or the DBR section of the DBR device, as the EAM layers must be capable of modulating the optical radiation at the operating wavelength of the DBR device between substantially transparent and absorbing states upon the application of an electrical current through the EAM device.

Although it is possible to form such a tuneable DBR-EAM device, either of the above prior art approaches introduces significant manufacturing difficulties. In the first approach, it is necessary to align optically discrete DBR and EAM devices and then to bond these to a supporting surface. In the second approach, it becomes necessary to process the III-V material in two sequential etch and re-growth processes, and to maintain vertical alignment between three separately formed active layers—two in the DBR device and a third in the EAM device. The difficulties add significantly to the finished cost of a tuneable optoelectronic transmitter component and negate some of all of the cost advantage to of not having to stock a number of fixed wavelength components to cover a particular spread of operating wavelengths.

It is an object of the present invention to provide a more convenient optoelectronic component, for example a laser diode source of optical radiation, having a Distributed Bragg Reflector (DBR) device and an Electro-absorption Modulator.

According to the invention, there is provided a semiconductor optoelectronic component, comprising a waveguide section for guiding optical radiation, a Distributed Bragg Reflector (DBR) section for wavelength-selecting optical radiation received from the waveguide section and an Electro-absorption Modulator (EAM) section for modulating optical radiation received from the DBR section, in which each section has a waveguide layer for conveying said optical radiation, said sections being monolithically integrated on a common semiconductor substrate, the DBR section lying between the waveguide section and the EAM section with the waveguides of adjacent sections being butt-coupled and aligned so that optical radiation may be conveyed between adjacent sections.

The optical radiation may be visible or invisible optical radiation, and in particular may be near-infra-red optical radiation at around 1310 nm or 1550 nm.

The waveguide section and the EAM section each may comprise a plurality of n-type and p-type grown layers above a common substrate, in which:
a) each of said n-type grown layers in one of said waveguide and EAM sections has a corresponding n-type grown layer in the other of the said waveguide and EAM sections; and
b) each of said p-type grown layers in one of said waveguide and EAM sections has a corresponding p-type grown layer in the other of the said waveguide and EAM sections.

In each of said waveguide and EAM sections (and with respect to the common substrate), there may be a buffer layer immediately beneath the corresponding waveguide layer, and a cap layer immediately above the corresponding waveguide layer.

The waveguide section and the EAM sections may have a common buffer layer that extends contiguously between said sections and beneath the waveguide layer of the waveguide layer of the EAM section.

In an embodiment of the invention, the waveguide layer of the waveguide section is thicker than the waveguide layer of the EAM section.

Also in an embodiment of the invention, each of said sections has a common buried mesa structure containing the respective waveguide layer. The mesa structure rises above the common substrate and is bounded by commonly grown semiconductor layers that extend between each of said sections and which form an electrical current restriction structure adjacent said buried mesa structure.

At least the DBR and EAM sections may each comprise at least one respective electrical contact by which an electrical current may be applied through the respective waveguide layer.

The waveguide section may comprise or consist of a laser diode section for generating optical radiation. The waveguide layer of the waveguide section is then a laser diode waveguide layer. The laser and DBR sections are then arranged such that the wavelength of said generated optical radiation is stabilized by the DBR section.

The laser diode section may comprise at least one respective electrical contact by which an electrical current may be applied through the laser diode waveguide layer.

Also according to the invention, there is provided a method of fabricating a semiconductor optoelectronic component comprising the steps of:
i) growing on a common semiconductor substrate semiconductor material to form a plurality of semiconductor layers including a waveguide layer;
ii) using the technique of selective area growth to enhance in a first area the semiconductor material growth of at least said waveguide layer relative to the growth of said semiconductor material in a second area;
iii) removing in a third area that lies between the first area and the second area at least some of said grown semiconductor material including in said third area at least said waveguide layer; and
iv) growing in said third area semiconductor material to form a waveguide layer that is butt-coupled and aligned with the adjacent waveguide layers in each of the first and second areas so that optical radiation may be conveyed between adjacent waveguides in the first, second and third areas.

The enhanced growth in the first area may be manifested as an increased rate of growth, and hence increased ultimate thickness of at least the waveguide layer and/or enhanced concentration of p-type or n-type dopants and/or a controlled change in composition due to a variation in III-V ratio in the semiconductor material.

The method may further comprise the steps of:
v) forming the first area a waveguide section for guiding optical radiation;
vi) forming in the third area a Distributed Bragg Reflector (DBR) section for wavelength-selecting optical radiation received from the waveguide section; and
vii) forming in the second area an Electro-absorption Modulator (EAM) section for modulating optical radiation received from the DBR section.

In an embodiment of the invention, step ii) takes advantage of a transition region between the first area and the second area in which there is a tapering of the selectively enhanced growth. The waveguide layer in the transition region is removed, for example by etching, and replaced by the growth waveguide layer in at least part of said third area.

The invention will now be described by way of example, with reference to the accompanying drawings, in which:

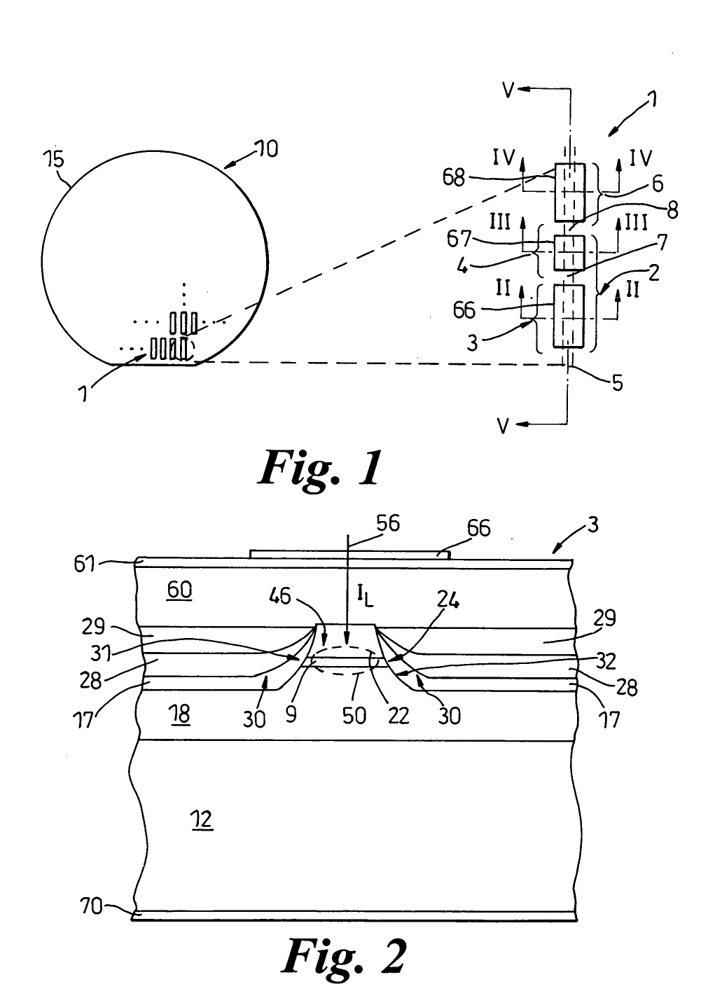

FIG. 1 is a schematic plan view of a monolithically integrated optoelectronic component according to the invention, having a Distributed Bragg Reflector (DBR) device having a laser section and a DBR section which is butt-coupled with an Electro-absorption Modulator (EAM) device on a common substrate;

FIG. 2 is a schematic transverse cross-section of the laser section of the DBR device of FIG. 1, taken along the line II-II, showing a buried heterostructure semiconductor laser junction comprising an active layer within a buried mesa stripe, a current conduction region for channelling current to the active layer, and a pair of current confinement regions either side of the buried mesa stripe;

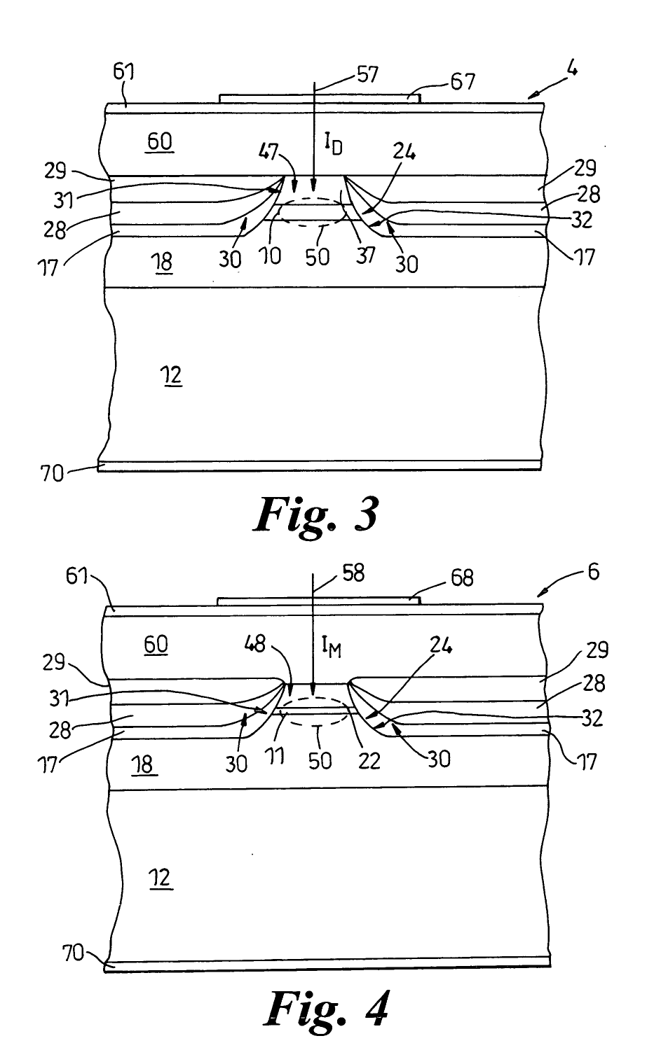

FIG. 3 is a schematic transverse cross-section of the DBR section of the DBR device of FIG. 1, taken along the line III-III, a DBR waveguide in the buried mesa stripe, a current conduction region for channelling current to the DBR waveguide, and a pair of current confinement regions either side of the DBR waveguide;

FIG. 4 is a schematic transverse cross-section of the EAM section of FIG. 1, taken along the line IV-IV, a modulation waveguide in the buried mesa stripe, a current conduction region for channelling current to the modulation waveguide, and a pair of current confinement regions either side of the modulation waveguide;

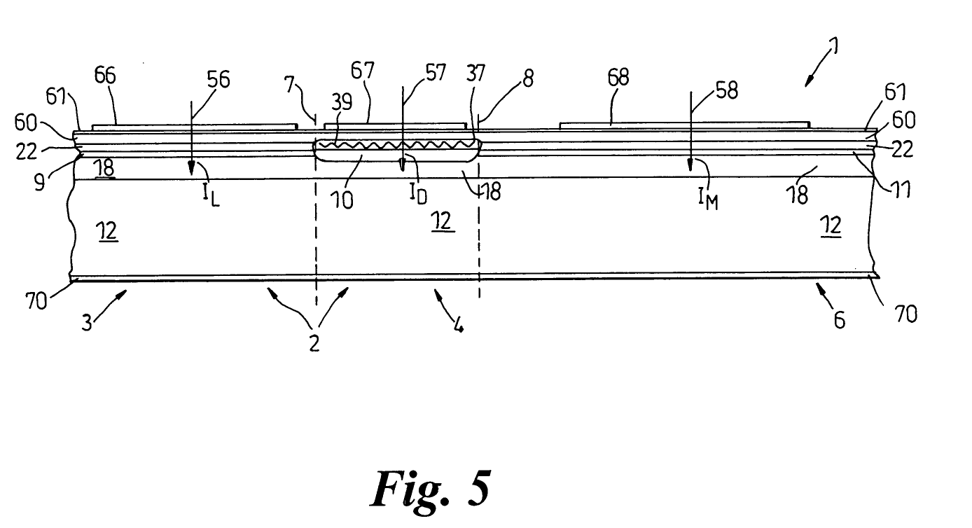

FIG. 5 is a schematic longitudinal cross-section of the DBR device and EAM section taken along the line V-V of FIG. 1; and

FIGS. 6A, 6B and 6C are schematic longitudinal cross-section views similar to that of FIG. 5 that illustrate a method according to the invention for forming the monolithically integrated optoelectronic component of the invention.

FIG. 1 shows a schematic plan view of a finished III-V semiconductor material wafer 15 on which have been fabricated a number of monolithically integrated III-V optoelectronic components 1 according to the invention. The component has a Distributed Bragg Reflector (DBR) device 2 having a laser section 3 and a DBR section 4. These sections 3, 4 are elongate and extend along an optical axis 5 which extends in one direction towards a similarly elongate and aligned Electro-absorption Modulator (EAM) section 6. The DBR section 4 is butt-coupled with both the laser section 3 and the Electro-absorption Modulator (EAM) section 6 at respective junctions 7, 8.

Reference is now made also to FIGS. 2 to 5, which show respectively the structures of the laser and DBR sections 3, 4 of the DBR device 2, and the EAM section 6, and also to FIGS. 6 to 9 which illustrate how these devices 2, 6 are monolithically integrated on a common InP substrate 12. For the purposes of clarity, these Figures are schematic only, and do not show dimensions to scale.

FIG. 2 shows a transverse cross section through the laser diode section 3 of the DBR device. The laser diode section 3 has a buried heterostructure laser diode waveguide layer 9 suitable for use as a transmitter in a fibre-optic link operating between 1.27 and 1.6 μm.

FIG. 3 shows a transverse cross-section through the DBR section 4 of the DBR device. The DBR section 4 has a buried grating waveguide 10 suitable for stabilising the wavelength of the laser output from the laser diode section 3.

FIG. 4 shows a transverse cross-section through the EAM section 6. The EAM section has a buried waveguide 11 suitable for modulating the wavelength-stabilised output of the DBR device 2.

Referring now also to FIG. 6, the devices 2, 6 are formed starting from an initial wafer that is around 50 mm in diameter, and that has an n-InP substrate 12 doped to around 10¹⁹ cc⁻¹, on which is grown a number of n-type and p-type III-V semiconductor layers. These layers are deposited using well-known MOCVD techniques. The p-type dopant is zinc, and the n-type dopant is sulphur.

The first grown layer is a 2 μm thick n⁻-InP buffer layer 18 doped to around 10¹⁸ cc⁻¹. Then, using well-known fabrication technology, the processed wafer 5 is coated with an oxide layer. The oxide layer may be SiO₂ deposited by a plasma enhanced chemical vapour deposition (PECVD) process. It should, however, be noted that silicon nitride would be a suitable alternative choice to SiO₂. As shown in FIG. 6, the oxide layer is photolithographically patterned with a photoresist to leave a patterned mask consisting of pairs of elongate parallel masked areas 16. Each pair of masked areas defines therebetween a confined rectangular stripe area 26 on the exposed surface of the buffer layer 18, as shown in FIG. 6.

An active waveguide layer 9, 11 is then grown on the buffer layer 18 of the non-masked portions of the processed wafer 25 according to known techniques for fabricating planar active layers for a laser diode. The active layer could be a bulk region or a strained multiple quantum well (SMQW) structure. An example of an SMQW device is discussed in W. S. Ring et al, Optical Fibre Conference, Vol. 2, 1996 Technical Digest Series, Optical Society of America. The type of active layer employed is not critical to the invention.

The active layer does not grow on the paired masks 16. The masks 16 therefore control where the active layer is deposited. This technique is known as selective area growth (SAG). The paired arrangement of masks 16 enhances the growth rate of the semiconductor material and concentration of group III component in region 26 relative to 18.

As can be seen from a comparison of FIGS. 2 and 4, the laser active waveguide layer 9 therefore is therefore thicker than the EAM active layer 11. In the present example, the laser active waveguide layer 9 grows to be about 200 nm thick, and the EAM active waveguide layer 11 grows to be about 180 nm thick.

In the present example, the laser diode section 3 has a quaternary multiple quantum well (MQW) InₓGa₁₋ₓAs_{1-y}P_{y} active layer 9 that may be between about 100 nm to 300 nm thick. As the EAM section 6 is grown during the same step, the EAM also has a quaternary MQW active layer 11. The active waveguide layer 11 is thinner by around 10% compared to the active waveguide layer 9 due to difference in growth rate. The variation in thickness and composition leads to a variation in photoluminescence (PL) wavelength (and bandgap). The PL wavelength of the laser diode is around 1550 nm (lower bandgap) and the PL wavelength of the EAM is around 1480 nm (higher bandgap). Thus the EAM waveguide is transparent at the laser diode operating wavelength of 1550 nm as the absorption edge of the EAM is significantly further away in order to avoid absorption in the unbiased condition. The EAM active waveguide layer 11 is thinner than the laser section active waveguide layer 9, and may be about 80 to 250 nm thick.

The rectangular area 26 therefore defines an area of enhanced growth of the active waveguide layer 9 for the laser section 3.

A typical spacing for between the paired masks 16 is about 10 to 30 μm, and the typical length is about 300 to 500 μm. Each of the masks 16 has a width comparable to the spacing between masks, for example being about 20 μm wide. The width and spacing is engineered to control the SAG enhancement.

There is a transition region between the active waveguide layers 9, 11 for the laser section 3 and the EAM section 6, with the different thickness and compositions grading into each other over a distance of about 100 μm.

The active waveguide layers 9, 11 are then topped by a cladding layer 22, formed from p⁺-InP material, grown to be between about 100 nm to 1 μm thick. Again the growth is selective because the cladding layer 22 is not formed over the paired masks 16.

The paired masks 16 are then removed with 10:1 buffered HF acid to expose the buffer layer 18 beneath the masks 16, and a second patterned mask consisting of pairs of discontinuous stripes areas 21, 21′ centrally aligned above the device axis 5 are deposited on the wafer 5, using similar process steps to that described above for the first masks 16. One of the mask areas 21 lies parallel with and fully between the rectangular depressions 16′ left by the first masks 16 in an area where the initial selective growth has been relatively enhanced. The other of the mask areas 21′ lies at a distance from the depressions 16′.

The second patterned mask 21, 21′ defines and protects the regions of the laser diode and EAM sections illustrated in FIG. 7 of which are around 10 μm wide and equidistant from the end of the rectangular depressions 16′ left by the first masks 16. The first of which 17 extends over enhanced growth active waveguide layer 9 and the second 18 over a portion of the non-enhanced active waveguide layer 11 for the EAM section 6. FIG. 7 illustrates the processed wafer 35 at this stage of production.

The exposed active and cladding layers 9, 11, 22 inside the unmasked area 23 are then removed in a wet-etch process which cuts down into the buffer layer 18. It would, however, be possible to use a reactive ion dry etching process. The DFB section 4 may then be formed from material deposited between the paired stripe areas 21, 21′.

The active waveguide layer 10 for the DBR section is then grown on the buffer layer 18 of the non-masked portions of the processed wafer 25 according to known butt-coupling techniques for fabricating planar active layers for a DBR device. As shown in FIG. 3, this active waveguide layer 10 is thicker than the adjacent active waveguide layers 9, 11 for the laser section 3 and the EAM section 6.

A p⁺-InP material cladding layer 37 is then grown over the DBR active waveguide layer 10. The formation of the DBR cladding layer 37 also involves using known techniques (for example by e-beam or holographic lithography) to form a DBR grating 39 in the cladding layer, for example by forming a periodically etched layer of a material such as GaInAsP. Alternatively, the grating may be formed in the buffer layer 18 beneath the subsequently deposited DBR active waveguide layer 10.

Because the DBR active waveguide layer is selectively grown in a gap etched between the laser section 3 and EAM section, the DBR section 4 is butt-coupled with the adjacent laser section 3 and EAM section 6 to form a monolithically integrated optoelectronic component 1. The active waveguide layers 9, 11 of the laser section 3 and EAM section are automatically self-aligned in the longitudinal direction along the component axis 5, and therefore the DBR active waveguide layer 10 is also automatically aligned with the adjacent active waveguide layers 9, 11 as long as the DBR active waveguide layer is growth to the correct level above the component substrate 12. The invention makes beneficial use of the fact that the thickness of the DBR active waveguide layer 10 can be greater than the thicknesses of the adjacent butt-coupled active waveguide layers 9, 11, as shown in most clearly in FIG. 5, in order to achieve this alignment.

After this, the second mask areas 21, 21′ are removed with 10:1 buffered HF acid.

A set of third patterned masks 41 is deposited on the wafer 45 as shown in FIG. 8, using similar process steps to that described above for the first and second masks 16, 21, 21′. Each of the third masks 41 covers stripes that run parallel to and between the paired depressions 16′ left by the paired first masks 16. The third patterned masks 41 extend fully between neighbouring paired depressions so that each mask stripe 41 extends the full length of each of the DBR device 2 and EAM section 6 that are ultimately formed. FIG. 8 illustrates the processed wafer 45 at this stage of production.

The exposed cladding layers 22, 37 outside the masked stripes 41 are then removed in a wet-etch process, which cuts down into the buffer layer 18. It would, however, be possible to use a reactive ion dry etching process. The unmasked grown layers 9, 10, 11, 18, 22 and 37 are removed in all areas except along a set of parallel mesa stripe 24 structures defined by the mask stripes 41. In FIGS. 2, 3 and 4, the mesa stripe 24 extends perpendicular to the plane of the drawing, and rises above the level of the surrounding etched buffer layer 18. The mesa stripe 24 has left and right opposite side walls 31, 32 that together with the buffer layers 18 and the cladding layers 22, 37 form current conduction regions 46, 47 and 48 for respective applied currents 56 (IL), 57 (ID), 58 (IM) to the laser section 3, DBR section 4 and EAM section 6.

As can be seen from the cross-section of FIG. 5, the three active waveguide layers 9, 10, 11 are longitudinally aligned at the butt-coupled junctions 7, 8 between the laser section 3, DBR section 4 and EAM section 6. This together with the mesa structure 24 has the effect of guiding an optical mode 50 along the active waveguide layers 9, 10, 11 within the stripe 24.

The laser current 56 may be applied to pump and drive the laser to generate an optical mode 50. The DBR current 57 may be varied in order to vary the effective refractive index of the DBR active waveguide layer, and hence tune the wavelength of the optical mode 50. The EAM current 58 may be modulated to shift a band absorption edge in the EAM active waveguide layer and impart a similar modulation on the optical mode 50.

The wet etch process produces mesa side walls 31, 32 that slope laterally away from the active layer. A dry etch process would produce side walls that are more closely vertical.

The width of the mesa stripe 24 varies depending on the particular device, but for opto-electronic devices such as laser diodes, the mesa stripe 24 is usually between 1 μm and 3 μm wide. The mesa strip 24 rises 1 μm to 3 μm above the surrounding buffer layer 18.

A current confinement or blocking structure 30 is then grown on the etched device up to approximately the level of the patterned stripe mask 41. The structure 30 includes a number of layers adjacent the buffer layer 18 including a first p-doped InP layer 17 having a dopant concentration about 1×10¹⁸ cc⁻¹ and above this, an n-doped InP layer 28, having a dopant concentration of at least about 1×10¹⁸ cc⁻¹, grown above the aluminium bearing layer. The n-doped InP layer 28 preferably has a substantially constant dopant concentration at least as high as the highest dopant concentration in the p-type layer 17. Finally, a second p-doped InP layer 29 having a dopant concentration about 1×10¹⁸ cc⁻¹ is deposited on the n-doped InP layer 28.

The thicknesses of the n-doped layer 28 is about 0.5 μm and the thickness of the first p-doped layer 17 is about 0.4 μm. These InP layers 17, 28 form a p-n junction that in use is reverse biased and hence insulating when the conduction region 14 is forward biased.

The first p-doped layer 17 should be between about one-tenth and one-half the thickness of the n-doped layer 28, that is between about 50 nm and about 250 nm thick.

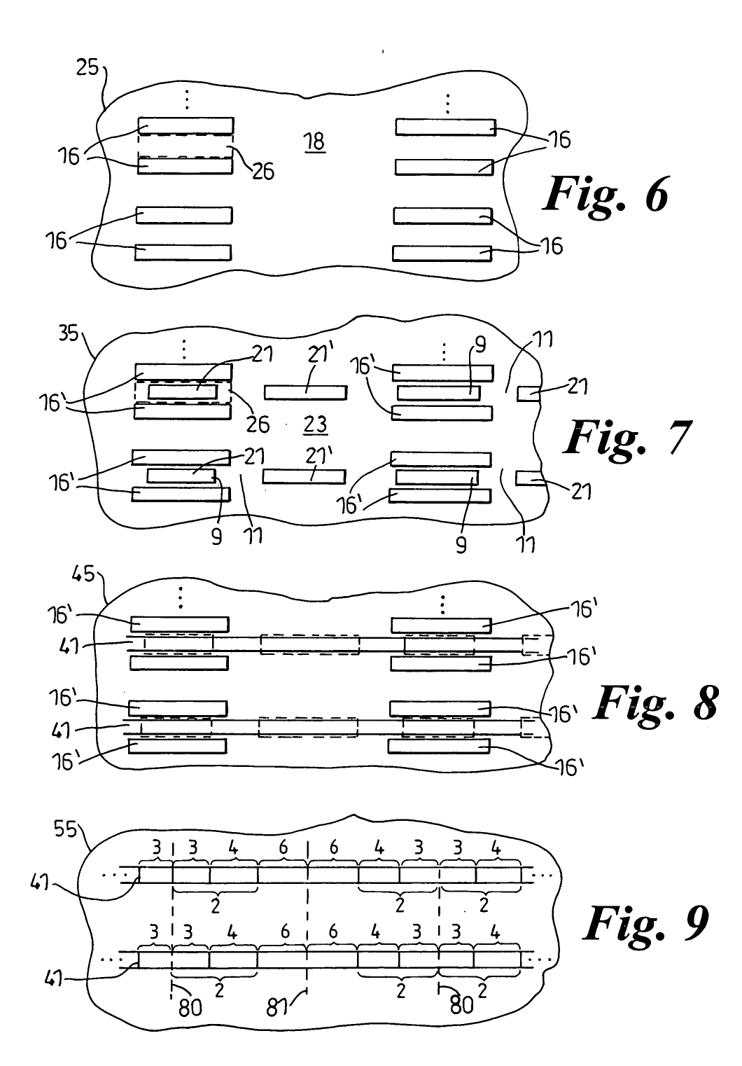

After deposition of the semiconductor layers 17, 28, 29 used to form the current blocking structure 30, the oxide layer mask 41 is removed with 10:1 buffered HF from the mesa strip 24 to expose again the cladding layers 22, 37. As shown in FIG. 9, this results in an etched and overgrown wafer 55 comprising the substrate 12, the mesa stripe 24, the layers 17, 28, 29 abutting the opposite sides 31, 32 of the mesa stripe 24.

As also shown in FIG. 9, the arrangement of the masks 16, 21, 21′ is such that the adjacent components 1 along the axis 5 have laser, DBR and EAM sections 3, 4, 6 arranged in opposite order so that one pair adjacent components 1 will have laser sections 3 formed from adjacent portions of the wafer 15, and the next adjacent pair of components will have an EAM section formed from adjacent portions of the wafer 15.

An upper cladding layer 60 formed from highly doped p⁺-InP is then grown above the cladding layers 22, 37 of the mesa stripe 24 and the second p-doped InP layer 29 of the current blocking structure 30, up to a thickness of about 2 μm to 3 μm. The final semiconductor layer is a 100 nm to 200 nm thick ternary cap layer 61 is deposited on the upper cladding layer 60. The cap layer 61 is formed from p⁺⁺-GaInAs, very 19-1 highly doped to greater than 10¹⁹ cc⁻¹, in order to provide a good low resistance ohmic contact for electrical connection to the three current conduction regions 46, 47, 48 of the mesa stripe 24. As an alternative to a ternary cap layer, it is possible to use a quaternary InGaAsP cap layer, or both InGaAsP and InGaAs layers.

An isolation etch through the ternary cap layer is then performed in order to help electrically isolate the three sections from each other and to help prevent cross-talk between the three sections of the device. In this isolation etch, the InGaAs cap layer 61 is then etched in photolithographically defined areas down to the second p-doped InP layer 29.

Standard metal layers for three electrical 66, 67, 68 contacts to the three portions 3, 4, 6 of each of the optoelectronic components 1 are then vacuum deposited on the cap layer 61 using well known techniques, followed by metal wet etch in photolithographically defined areas. The remaining metal forms three contact pads 66, 67, 68 with good ohmic contact through the cap layer 61.

The resulting wafer 15 is then thinned to a thickness of about 70 μm to 100 μm in a standard way, in order to assist with cleaving. Standard metal layers 70 are then deposited by sputtering on the rear surface of the wafer 15, so enabling electrical contact to be made to the n-side of the devices.

The wafer is then inscribed and cleaved along cleave lines 80 between adjacent laser sections 3 and cleave lines 81 between adjacent EAM sections 6 in a conventional process that produces transverse bars about 500 μm wide. Then each bar is cleaved into individual devices 200 μm wide. The final individual cleaved device 1 is about 500 μm long (i.e. in the direction of the mesa 24) and about 200 μm wide.

Although not shown, after testing the device 1 may be packaged in an industry standard package, with a single mode optical fibre coupled with a spherical lens to an output facet of the laser diode, and with gold bond wires thermal compression bonded onto the metalised contacts 66, 67, 68.

Although the present invention has been described specifically for the example of an InGaAsP/InP mesa waveguide laser diode in combination with a DFB section for stabilizing the optical wavelength and EAM modulator for modulating the optical radiation, the invention is applicable to any optoelectronic waveguide device requiring both wavelength stabilization or selection from the DBR device in combination with optical modulation from the EAM section. Therefore, the invention may for example, also be employed with an optical waveguide in an optoelectronic receiver component in which the DBR selects a wavelength to be received. Similarly, the invention may be employed in an optical amplifier component in which a selected wavelength is to be amplified, or in a non-amplifying or passive selective wavelength waveguide splitter component. A non-amplifying waveguide component according to the invention may have electrical contacts just for the DFB and EAM portions of the component.

It should be noted that the invention is not limited to the use of a mesa current blocking structures of the type described above, and may employ other current confinement techniques and structures.

The invention described above has been described in detail for a device based on an n-InP substrate. However, it is to be appreciated that the invention can also be applied to devices based on a p-InP substrate.

The invention therefore provides a convenient optoelectronic component for stabilizing or selecting optical radiation of a desired wavelength device and an economical method for manufacturing such a device.

1. A semiconductor optoelectronic component, comprising a waveguide section for guiding optical radiation, a Distributed Bragg Reflector (DBR) section for wavelength-selecting optical radiation received from the waveguide section and an Electro-absorption Modulator (EAM) section for modulating optical radiation received from the DBR section, in which each section has a waveguide layer for conveying said optical radiation, said sections being monolithically integrated on a common semiconductor substrate, the DBR section lying between the waveguide section and the EAM section with the waveguides of adjacent sections being butt-coupled and aligned so that optical radiation may be conveyed between adjacent-sections.

2. A semiconductor optoelectronic component as claimed in claim 1, in which the waveguide section and the EAM section each comprise a plurality, of layers including at least one n-type layer and at least one p-type grown layer above a common substrate, in which:
a) each of said n-type grown layers in one of said waveguide and EAM sections has a corresponding n-type grown layer in the other of the said waveguide and EAM sections; and
b) each of said p-type grown layers in one of said waveguide and EAM sections has a corresponding p-type grown layer in the other of the said waveguide and EAM sections.

3. A semiconductor optoelectronic component as claimed in claim 2, in which in each of said waveguide and EAM sections and with respect to the common substrate, there is a buffer layer immediately beneath the corresponding waveguide layer, and a cap layer immediately above the corresponding waveguide layer.

4. A semiconductor optoelectronic component as claimed in claim 3, in which the waveguide section and the EAM section have a common buffer layer that extends contiguously between said sections and beneath the waveguide layers of the waveguide layer of the EAM section.

5. A semiconductor optoelectronic component as claimed in claim 1, in which the waveguide layer of the waveguide section is thicker than the waveguide layer of the EAM section.

6. A semiconductor optoelectronic component as claimed in claim 1, in which the waveguide layer of the DBR section is thicker than the waveguide layers of either the waveguide section or the EAM section.

7. A semiconductor optoelectronic component as claimed in claim 1, in which each of said sections has a waveguide layer which is elongate and which extends along a common axis.

8. A semiconductor optoelectronic component as claimed in claim 1, in which each of said sections has a common buried mesa structure containing the respective waveguide layer (9,10,11), said mesa structure rising above the common substrate and being bounded by commonly grown semiconductor layers that extend between each of said sections and which form an electrical current restriction structure adjacent said buried mesa structure.

9. A semiconductor optoelectronic component as claimed in claim 1, in which at least the DBR and EAM sections each comprise at least one respective electrical contact by which an electrical current may be applied through the respective waveguide layer.

10. A semiconductor optoelectronic component as claimed in claim 1, in which the waveguide section comprises or consists of a laser diode section for generating optical radiation, the waveguide layer of the waveguide section being a laser diode waveguide layer and the laser and DBR sections being arranged such that the wavelength of said generated optical radiation is stabilized by the DBR section.

11. A semiconductor optoelectronic component as claimed in claim 10, in which the laser diode section comprises at least one respective electrical contact by which an electrical current may be applied through the laser diode waveguide layer.

12. A method of fabricating a semiconductor optoelectronic component comprising:
growing on a common semiconductor substrate semiconductor material to form a plurality of semiconductor layers including a waveguide layer;
using the technique of selective area growth to enhance in a first area the semiconductor material growth of at least said waveguide layer relative to the growth of said semiconductor material in a second area;
removing in a third area that lies between the first area and the second area at least some of said grown semiconductor material including in said third area at least said waveguide layer; and
growing in said third area semiconductor material to form a waveguide layer that is butt-coupled and aligned with the adjacent waveguide layers in each of the first and second areas so that optical radiation may be conveyed between adjacent waveguides in the first, second and third areas.

13. A method of fabricating a semiconductor optoelectronic component as claimed in claim 12, comprising:
forming the first area a waveguide section for guiding optical radiation;
forming in the third area a Distributed Bragg Reflector (DBR) section for wavelength-selecting optical radiation received from the waveguide section; and
forming in the second area an Electro-absorption Modulator (EAM) section for modulating optical radiation received from the DBR section.

14. A method of fabricating a semiconductor optoelectronic component as claimed in claim 12, wherein using the technique of selective area growth to enhance in a first area the semiconductor material growth of at least said waveguide layer relative to the growth of said semiconductor material in a second area, in between the first area and the second area, there is a transition region in which there is a tapering of the selectively enhanced growth between the first area and said second area, said transition region forming at least part of said third area.
